(19) United States
(12) Patent Application Publication
(10) Pub. No.: US 2015/0228530 A1
(43) Pub. Date: Aug. 13, 2015

(54) PROCESSING ARRANGEMENT WITH TEMPERATURE CONDITIONING ARRANGEMENT AND METHOD OF PROCESSING A SUBSTRATE

(71) Applicant: Oerlikon Advanced Technologies AG, Balzers (LI)

(72) Inventors: Hartmut Rohrmann, Schriesheim (DE); Martin Kratzer, Feldkirch (AT)

(73) Assignee: Oerlikon Advanced Technologies AG, Balzers (LI)

(21) Appl. No.: 14/424,172

(22) PCT Filed: Aug. 22, 2013
(86) PCT No.: PCT/CH2013/000148

§ 371 Date: Feb. 26, 2015

Related U.S. Application Data
(60) Provisional application No. 61/693,406, filed on Aug. 27, 2012.

(51) Int. Cl. H01L 21/687; C23C 14/50; C23C 14/14; H01J 37/34; C23C 14/32; C23C 14/34

(52) U.S. Cl. CPC H01L 21/68735; C23C 14/325; C23C 14/34; C23C 14/14; H01J 37/3426; C23C 14/50; H01J 2237/332

(57) ABSTRACT

A substrate processing arrangement exhibits a thermal cavity with two reflective surfaces and a carbon heater for effectively heating substrates to temperatures of 750° C. and more. It has been shown, that even substrates with low absorption properties in the infrared part of the spectrum (glas, silicon, sapphire) can be effectively heated by “sandwiching” a substrate and a heating element between two reflective surfaces, which can be established by a mirror and the target of a PVD source.

The present invention refers to processing arrangement with a substrate holder and temperature conditioning arrangement, which is construed as “thermal cavity”. It further refers to a method for processing a substrate in such a temperature conditioning arrangement.

### DEFINITIONS

Processing in the sense of this invention includes any chemical, physical or mechanical effect acting on substrates.

Substrates in the sense of this invention are components, parts or workpieces to be treated in a processing apparatus. Substrates include but are not limited to flat, plate shaped parts having rectangular, square or circular shape. In a preferred embodiment this invention addresses essentially planar, circular substrates, such as wafers. The material of such wafers may be glass, semiconductor, ceramic or any other substance able to withstand the processing temperatures described.

A vacuum processing or vacuum treatment system/apparatus/chamber comprises at least an enclosure for substrates to be treated under pressures lower than ambient atmospheric pressure plus means for processing said substrates.

A chuck or clamp is a substrate holder adapted to fasten a substrate during processing. This clamping may be achieved, inter alia, by electrostatic forces (electrostatic chuck ESC), mechanical means, vacuum or a combination of aforesaid means. Chucks may exhibit additional facilities like temperature control components (cooling, heating) and sensors (substrate orientation, temperature, warping, etc.)

CVD or Chemical Vapour Deposition is a chemical process allowing for the deposition of layers on heated substrates. One or more volatile precursor material(s) are being fed to a process system where they react and/or decompose on the substrate surface to produce the desired deposit. Variants of CVD include: Low-pressure CVD (LPCVD)—CVD processes at sub-atmospheric pressures. Ultrahigh vacuum CVD (UHVCVD) are CVD processes typically below 10⁻⁶ Pa/10⁻⁷ Pa. Plasma methods include Microwave plasma-assisted CVD (MPCVD) and Plasma-Enhanced CVD (PECVD). These CVD processes utilize plasma to enhance chemical reaction rates of the precursors.

Physical vapor deposition (PVD) is a general term used to describe any of a variety of methods to deposit thin films by the condensation of a vaporized form of a material onto a surface of a substrate (e.g. onto semiconductor wafers). The coating method involves purely physical processes such as high temperature vacuum evaporation or plasma sputter bombardment in contrast to CVD. Variants of PVD include cathodic arc deposition, electron beam physical vapor deposition, evaporative deposition, sputter deposition (i.e. a glow plasma discharge usually confined in a magnetic tunnel located on a surface of a target material).

The terms layer, coating, deposit and film are interchangeably used in this disclosure for a film deposited in vacuum processing equipment, be it CVD, LPCVD, plasma enhanced CVD (PECVD) or PVD (physical vapour deposition).

### BACKGROUND OF THE INVENTION

Chuck arrangements, by which substrates are positioned and held during processing in a vacuum processing chamber and are temperature conditioned during such processing, are widely known. Such conditioning shall be understood to include heating up a substrate to a desired temperature, keeping a substrate at a desired temperature and cooling a substrate to remain at a desired processing temperature, e.g. when the processing itself tends to overheat a substrate.

In Prior Art a substrate is commonly held upon a chuck arrangement by electrostatic forces, by gravity only, by means of a retaining weight-ring resting upon the periphery of the substrate being processed or by means of clamps or clips fixating said substrate.

A chuck arrangement usually includes a rigid base or support for the substrate to be placed upon; said support again is heated by resistive heaters or by lamps (e.g. halogen lamps). In many Prior Art applications of temperature conditioning arrangements the heat transfer is then accomplished by means of a direct contact between the support and the substrate. However, the quality of the heat transfer strongly depends on how good the contact can be established. If the substrate is not perfectly plane or one of substrate and support are warping during heating, the contact will not be fully surfaced. Then a mixture of heat conduction and radiation will be responsible for the heat transfer, which may result in inhomogeneous heat distribution on the substrate. Moreover thermally induced mechanical stress may harm the substrate. This problem has been solved in two ways: First by using mechanical means forcing support and substrate into a stronger contact (heat conduction). However, this may even enhance the mechanical stress on the substrate which may, especially for thin and/or brittle substrates, lead to substrate breakage. The second way is to use a backside gas contact. In such a case a gas is introduced between substrate support and substrate which will provide for heat transfer by a mixture of convection and conduction. Heat transport via gas contact however is not very effective, especially for high temperatures to be achieved. Thermal losses occur with the gas leaking away, besides that the gas should not negatively interfere with the process itself, which limits the choice of gases. Another problem occurs if the substrate to be processed needs to be treated on the full surface exposed to the processing means. In this case any clamping is impossible. Normally in such cases electrostatic chucks will be used which allow a safe and strong clamping. However, the electrostatic effect is strongly temperature dependent and will render ineffective especially for very high temperatures (i.e. >500° C.). Besides that, any electronics necessary to control the forces need to be cooled.

A further disadvantage arises from the use of resistive wires or halogen lamps for heating substrates. These are essentially linear or point-shaped heat sources; in order to properly distribute the heat over a surface one generally uses a metal block for dissipating the heat. This however adds thermal inertia and additional losses to the whole thermal conditioning arrangement. As an alternative, a rotating substrate support in relation to the heat source(s) may be foreseen. This however adds mechanical complexity to the overall construction and makes a clamping of the substrate mandatory.

It is thus the objective of the invention to provide for a thermal conditioning arrangement which is simple in construction, allows for clampless treatment of the substrate, requires no substrate rotation, has low thermal inertia, and achieves a substrate temperature of at least 500° to 1200°, preferably 750° C. to 1000°.

### BRIEF DESCRIPTION OF THE DRAWINGS

FIG. 1 shows a cross-section through a processing arrangement according to the invention

FIG. 2 shows a possible design for the heating element according to the invention.

FIG. 3 shows the alignment of a substrate and a heating element (top view)

### SUMMARY OF THE INVENTION

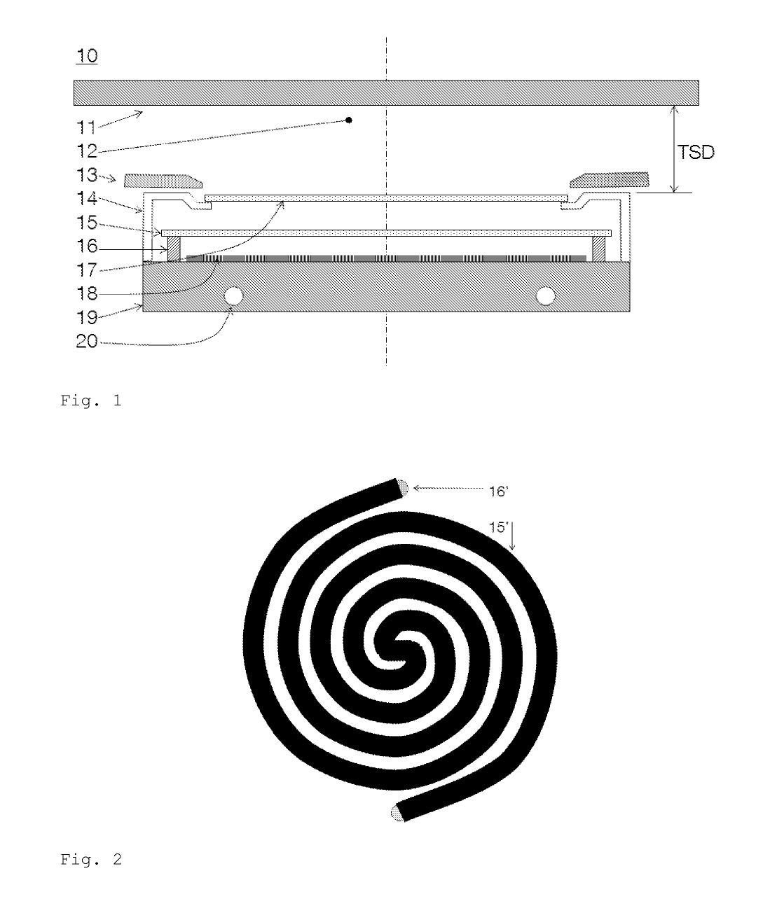

It is one object of the present invention to provide a processing arrangement with a temperature conditioning arrangement to be mounted to a vacuum treatment chamber, which allows a large number of different substrate processing, thereby additionally simplifying the overall structure of the temperature conditioning arrangement as known and as was exemplified with the help of FIG. 1.

This is reached by the processing arrangement and temperature conditioning arrangement to be mounted to a vacuum wafer treatment chamber, which comprises in this order:
a base 19 with an extended, essentially plane surface,
an essentially planar heating element 15 mounted above said base 19 in a plane parallel and distant to and facing the surface of base 19
a substrate support 14 construed to carry a substrate 17 at its periphery, said substrate 17 facing directly the heating element with one of its surfaces during operation
   wherein
a heat reflecting surface or mirror 18 is arranged on the surface of base 19
and no further clamping means exist to hold the substrate in place during operation

In a preferred embodiment said processing arrangement further comprises a source of treatment material, arranged in a further plane parallel to the substrate and heating element and directly facing the substrate during operation.

Said source of treatment material may be any of PVD, CVD or activated gas sources (e.g. for cleaning, after-treatment, surface modifications or etching).

A method of treating a substrate in a processing arrangement as described above comprises
Placing a substrate on the substrate support of respective processing arrangement
Heating up the substrate to a desired level
Treating the substrate in a manner as described above

### DETAILED DESCRIPTION OF THE INVENTION

A substrate processing apparatus 10 with a temperature conditioning arrangement comprises a base 19 to be arranged in a vacuum processing chamber. Said chamber or enclosure has been omitted in FIG. 1 and can be designed as known in the art, including necessary means for generating a vacuum, removing waste gases, electrical wiring and load/unload facilities for the substrate. On said base 19 a heating element 15 is arranged, preferably mounted in parallel to the surface of base 19 on post(s) 16 providing a clearance between base 19 and said heating element 15. The heating element can basically be chosen from prior art heating elements, such as resistive heaters, radiation heaters or, especially preferred, a carbon heater arrangement. In a plane again parallel to said base 19 and heating element 15 a substrate 17 can be arranged, preferably in a distance between 5 mm and 20 mm. Said substrate 17 is preferably held by a substrate support 14, which can be designed as a ring-shaped bearing area or as a selective support at the circumference of the substrate.

In the context of this invention it is important to note, that no active clamping, weight ring or clips are required. The substrate is placed on the substrate support 14 and held by its own weight. So no mechanical stress is being exerted by fastening means. In a further plane parallel to aforementioned base, heating element and substrate, a target 11 is being mounted. The target-substrate-distance TSD is being chosen between 4-10 cm, preferably 5-8 cm. Between substrate 17 and target 11 the processing space 12 is available. The processing space will exhibit plasma during sputtering. Working gases (reactive or inert) may be injected near the target edges from the side. PVD sputtering processes are known in the art and thus are not described herein in detail. Material is being plasma-sputtered from target 11 and being deposited on substrate 17. A shield 13 may be optionally foreseen to protect substrate support 14 from being covered with target material. Such shield 13 may be easily exchanged during maintenance intervals. As shown in FIG. 1 the shields are construed in such a way that a layer deposited on substrate 17 is covering the full surface facing the target 11.

The heating element 15, preferably a carbon heater, is a radiation-type heating element. In an embodiment of the invention, the carbon heating element is being connected to a power source able to deliver 3 kW of electrical power. The carbon element heats up to 2300° C. and allows substrate temperatures (in case of sapphire or silicon substrates) of 750° C. and more. In order to allow for an effective heat management, a mirror or reflective means 18, preferably with good reflective properties in the infrared part of the spectrum is being arranged directly on base 19 facing the heating element 15 (on the side averted from substrate 17, as shown in FIG. 1). It has been shown, that even substrates with low absorption properties in the infrared part of the spectrum (glass, silicon, sapphire) can be effectively heated by “sandwiching” a substrate 17 and a heating element 15 between two reflective surfaces, such as mirror 18 and target 11. Such a “thermal cavity” is highly effective, because the radiation from heating element 15 which is originating from both the front side facing the substrate 17 as well its backside is being directed and re-directed towards the substrate. The radiation is essentially being trapped and reflected between the two reflective surfaces until it is being absorbed by the substrate (or lost).

Base 19 is cooled, preferably by a fluid in channels 20 foreseen in the metal block. Preferably mirror 17 and substrate support 14 thus use base 19 as heat sink.

Heat-Reflective mirror 18 can be manufactured as a nickel coating or as an exchangeable thin nickel plate mounted onto base 19. Other high reflective materials with good reflectivity especially in the infrared part of the spectra are also useful.

The counterpart or second mirror to the cavity is target 11. Basically the same reflectivity requirements are valid as for mirror 17, however of course the layer to be deposited determines the choice of material. Examples for applicable materials are Al, Ti, Ag, Ta and their alloys.

Due to the efficiency of heating element 15 substrate support 14 has to be made from material able to withstand high temperatures. Titanium is a material of choice or high-tensile steel may be used.

The inventive substrate processing apparatus 10 is not limited to the use with a sputtering target 11 in a PVD application. It can be used in a CVD or PECVD application, wherein instead of target 11 a showerhead or another overhead processing gas inlet is being arranged. It is being understood, that the a.m. limitations and requirements for the “thermal cavity” quality need to be fulfilled by the showerhead or gas inlet in an equivalent manner. Materials like polished steel, Ni, Al could be used.

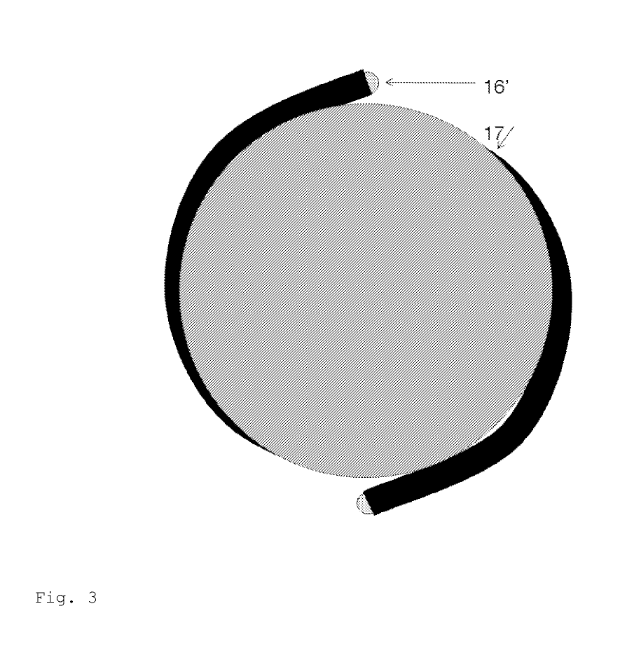

FIG. 2 is a top view on one embodiment of a heating element 15′. The posts 16′ are equivalent to posts 16 in FIG. 1. This embodiment comprises a double-spiral structure with electrical connectors lying outside. The heating element can be cut from a carbon-fibre plate or be pressed in a respective mould. Carbon-fibres or carbon fibre-composites are per se known and are available in the market. The shape of the heating element (width and thickness of the windings) can be optimized to allow for a homogeneous heating effect. In an embodiment a thickness of 2.5 mm had been chosen, which is a compromise of weight, stability of the material and the overall electrical resistance. In cross-section, a rectangular shape of the individual winding is preferred over square or round shapes.

The resulting structure can be self-supporting, depending on the diameter and thickness of the heating element. If a bending during operation occurs, the structure could be stabilized by means of ceramic rest.

FIG. 3 shows the alignment of a substrate 17 in relation to the heating element 15. It is preferred to arrange the electrical connection outside the effectively heated substrate area, since the connector will not exhibit the same working temperature as the heating element itself. Thus temperature inhomogeneities especially in the edge region of the substrate can be avoided. Consequently, the size of the heating element will be essentially the size of the substrate plus the extensions for the connectors.

The thermal conditioning arrangement is of course functional also for non-reflective targets 11 and/or highly absorptive substrates 17. A SiC substrate e.g. would not require a thermal cavity with two reflective surfaces. However, the arrangement of mirror 18 behind the heating element will still enhance the heating efficiency in this case.

The invention as described above can be used for circular, rectangular or square substrates of different sizes. It may be preferably used in substrate processing systems designed for processing of 4″, 6″, 8″ (200 mm) or 12″ (300 mm) wafer diameters. Due to the nature of its heating element intermediate sizes can be easily construed.

The temperature conditioning arrangement as described has a low thermal inertia due to its direct radiation heating principle. It can be advantageously used to allow a substrate heat-up quickly or in steps via varying the electrical power in steps. The same advantage applies to cooling down scenarios.

1. A substrate processing arrangement exhibiting a temperature conditioning arrangement including a thermal cavity with two reflective surfaces, said thermal cavity essentially comprising:
a base (19) with an extended, essentially plane surface,
an essentially planar heating element (15) mounted above said base (19) in a plane parallel and distant to and facing the surface of base (19)
a substrate support (14) construed to carry a substrate (17) at its periphery, said substrate (17) being spaced apart from, but facing directly the heating element with one of its surfaces during operation
wherein
a heat reflecting surface or mirror 18 is arranged on the surface of base 19;
a second reflecting means is arranged in a further plane parallel to the substrate and heating element on the other side of the substrate support (14) such that during operation substrate (17) is directly facing said reflecting means with another of its surfaces;
and no further clamping means exist to hold substrate (17) in place on substrate support (14) during operation.

2. A substrate processing arrangement according to claim 1, wherein heat reflecting surface or mirror (18) comprises a nickel coating or a nickel plate mounted to base (19).

3. A substrate processing arrangement according to claim 1 and/or 2, characterized in that said second reflecting means is a source of treatment material or target (11) of a physical vapour deposition source.

4. A substrate processing arrangement according to claim 1 and/or 2, characterized in that said second reflecting means is a showerhead or processing gas inlet of a CVD or PECVD source.

5. A substrate processing arrangement according to claims 1-4, wherein said second reflecting means' material comprises Al, Ti, Ag, Ta, and their alloys and Ni.

6. A substrate processing arrangement according to claims 1-5, wherein the distance between the plane of heating element (15) and the plane where substrate (17) is arranged during operation amounts to between 5-20 mm.

7. A substrate processing arrangement according to claims 1-6, characterized in that substrate support (14) is designed as ring-shaped bearing area or selective support at the circumference of the substrate.

8. A substrate processing arrangement according to claims 1-7, wherein the target-substrate distance TSD between the plane of the substrate (17) during operation and second reflecting means or target (11) respectively is being chosen to range from 4-10 cm.

9. A substrate processing arrangement according to claim 8, wherein the TSD is between 5-8 cm.

10. A substrate processing arrangement according to claims 1-9, characterized by a shield (13) arranged between second reflecting means or target (11) and substrate support (14), said shield (13) construed to protect substrate support (14) from being covered with treatment material while a layer deposited on substrate (17) is covering the full surface facing target (11).

11. A substrate processing arrangement according to claims 1-10, wherein heating element (15) is a resistive heater.

12. A substrate processing arrangement according to claims 1-10, wherein heating element (15) is a radiation type heater.

13. A substrate processing arrangement according to claims 1-10, wherein heating element (15) is a carbon heater.

14. A substrate processing arrangement according to claims 13, wherein said carbon heater has a double-spiral structure with electrical connectors lying outside.

15. A substrate processing arrangement according to claims 13 and/or 14, wherein the electrical connectors are arranged outside the effectively heated substrate area.

16. A method of treating a substrate in a processing arrangement comprising:
Placing a substrate (17) on a substrate support (14) of a substrate processing arrangement according to claim 1,
Heating up the substrate to a predefined temperature
Treating the substrate
